(19) United States
(12) Patent Application Publication
(10) Pub. No.: US 2007/0056843 A1
(43) Pub. Date: Mar. 15, 2007

(54) Method of processing a substrate using a large-area magnetron sputtering chamber with individually controlled sputtering zones

(75) Inventors: Yan Ye, Saratoga, CA (US); John White, Hayward, CA (US); Akihiro Hosokawa, Cupertino, CA (US); Hienminh H. Le, San Jose, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/225,923

(22) Filed: Sep. 13, 2005

(51) Int. Cl. C23C 14/32

(52) U.S. Cl. 204/192.1

(57) ABSTRACT

The present invention generally provides a method for processing a surface of a substrate in a physical vapor deposition (PVD) chamber that has a sputtering target that has separately biasable sections, regions or zones to improve the deposition uniformity. In general, aspects of the present invention can be used for flat panel display processing, semiconductor processing, solar cell processing, or any other substrate processing. In one aspect, each of the target sections of the multizone target assembly are biased at a different cathodic biases by use of one or more DC or RF power sources. In one aspect, each of the target sections of the multizone target assembly are biased at a different cathodic biases by use of one power source and one or more resistive, capacitive and/or inductive elements. In one aspect, the processing chamber contains a multizone target assembly that has one or more ports that are adapted deliver a processing gas to the processing region of the PVD chamber. In one aspect, the processing chamber contains a multizone target assembly that has one or more magnetron assemblies positioned adjacent to one or more of the target sections.

### BACKGROUND OF THE INVENTION

1. Field of the Invention

Embodiments of the present invention generally relate to substrate plasma processing apparatuses and methods that are adapted to deposit a film on a surface of a substrate.

2. Description of the Related Art

Physical vapor deposition (PVD) using a magnetron is one of the principal methods of depositing metal onto a semiconductor integrated circuit to form electrical connections and other structures in an integrated circuit device. During a PVD process a target is electrically biased so that ions generated in a process region can bombard the target surface with sufficient energy to dislodged atoms from the target. The process of biasing a target to cause the generation of a plasma that causes ions to bombard and remove atoms from the target surface is commonly called sputtering. The sputtered atoms travel generally toward the wafer being sputter coated, and the sputtered atoms are deposited on the wafer. Alternatively, the atoms react with a gas in the plasma, for example, nitrogen, to reactively deposit a compound on the wafer. Reactive sputtering is often used to form thin barrier and nucleation layers of titanium nitride or tantalum nitride on the substrate.

Direct current (DC) magnetron sputtering is the most usually practiced commercial form of sputtering. The metallic target is biased to a negative DC bias in the range of about −100 to −600 VDC to attract positive ions of the working gas (e.g., argon) toward the target to sputter the metal atoms. Usually, the sides of the sputter chamber are covered with a shield to protect the chamber walls from sputter deposition. The shield is typically electrically grounded and thus provides an anode in opposition to the target cathode to capacitively couple the DC target power to the plasma generated in the sputter chamber.

A magnetron having at least a pair of opposed magnetic poles is typically disposed near the back of the target to generate a magnetic field close to and parallel to the front face of the target. The induced magnetic field from the pair of opposing magnets trap electrons and extend the electron lifetime before they are lost to an anodic surface or recombine with gas atoms in the plasma. Due to the extended lifetime, and the need to maintain charge neutrality in the plasma, additional argon ions are attracted into the region adjacent to the magnetron to form there a high-density plasma. Thereby, the sputtering rate is increased.

However, conventional sputtering presents challenges in the formation of advanced integrated circuits on large area substrates, such a flat panel display substrates. Typically, for TFT applications, the substrate is a glass substrate with a surface area greater than about 2000 cm². Commonly, TFT processing equipment is generally configured to accommodate substrates up to about 1.5×1.8 meters. However, processing equipment configured to accommodate substrate sizes up to and exceeding 2.16×2.46 meters, is envisioned in the immediate future. One issue that arises is that it is generally not feasible to create a chamber big enough to maintain the surface area ratio of the cathode (target) to anode surface area commonly used in conventional sputter processing chambers. Trying to maintain the surface area ratio can lead to manufacturing difficulties due to the large size of the parts required to achieve the desired area ratio and processing problems related to the need to pump down such a large volume to a desired base pressure prior to processing. The reduced surface area of the anode relative to the large target surface area generally causes the density of the plasma generated in the processing region, which is generally defined as the region below the target and above the substrate, to vary significantly from the center of the target to the edge of the target. Since the anodic surfaces are commonly distributed around the periphery of the target, it is believed that the larger distance from the center of the target to the anodic surfaces, makes the emission of electrons from the target surface at the edge of the target more favorable, and thus reduces the plasma density near the center of the target. The reduction in plasma density in various regions across the target face will reduce the number of ions striking the surface of the target in that localized area and thus varying the uniformity of the deposited film across the surface of a substrate that is positioned a distance from the target face. The insufficient anode area problem will thus manifest itself as a film thickness non-uniformity that is smaller near the center of the substrate relative to the edge.

Therefore, there is a need for a method and apparatus that can form a more uniform plasma in a PVD processing chamber that will not generate particles and can overcome the other drawbacks described above.

### SUMMARY OF THE INVENTION

The present invention generally provides a method of depositing a thin film on a large area substrate, comprising: electrically biasing a first target section of a multizone target assembly at a first bias using a first power supply, electrically biasing a second target section of the multizone target assembly at a second bias using a second power supply, and controlling the deposition profile received on a substrate surface by controlling the bias supplied by the first power supply and the second power supply.

Embodiments of the invention may further provide a method of depositing a thin film on a substrate, comprising: electrically biasing a first target section of a multizone target assembly at a first bias using a first power supply, electrically biasing a second target section of a multizone target assembly at a second bias using a second power supply, positioning a first magnetron assembly over the first target section using a first actuator, wherein a magnet in the first magnetron is magnetically coupled to a processing region that is adjacent to a surface of the first target section, positioning a second magnetron assembly over the second target section using a second actuator, wherein a magnet in the second magnetron is magnetically coupled to the processing region that is adjacent to a surface of the second target section, and controlling the deposition profile received on a substrate surface by controlling the first bias delivered by the first power supply, the second bias delivered by the second power supply, the position of the first magnetron assembly and the position of the second magnetron assembly.

Embodiments of the invention may further provide a method of depositing a thin film on a substrate, comprising: providing a process gas to a processing region through a port formed in a multizone target assembly, wherein the processing region is formed between the multizone target assembly and a substrate positioned on a substrate support, and depositing a layer onto a surface of the substrate positioned on the substrate support by biasing a first target region of the multizone target assembly at a first bias and a second target region of the multizone target assembly at a second bias, wherein the first bias voltage is more cathodic than the second bias voltage.

Embodiments of the invention may further provide a method of depositing a thin film on a substrate, comprising: electrically biasing a first target section of a multizone target assembly at a first bias using a first power supply, electrically biasing a second target section of a multizone target assembly at a second bias using a second power supply, positioning a magnetron assembly over the first target section and the second target section using an actuator, wherein a first magnet in the magnetron assembly is magnetically coupled to a processing region that is adjacent to a surface of the first target section and a second magnet in the magnetron assembly is magnetically coupled to a processing region that is adjacent to a surface of the second target section, and controlling the deposition profile received on a substrate surface by controlling the first bias delivered by the first power supply, the second bias delivered by the second power supply, and the position of the magnetron assembly.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a vertical cross-sectional view of conventional physical vapor deposition chamber.

FIG. 2 is a vertical cross-sectional view of an exemplary physical vapor deposition chamber.

FIG. 3A schematically illustrates electrical connections to the target sections of a multizone target assembly in an exemplary physical vapor deposition chamber.

FIG. 3B schematically illustrates electrical connections to the target sections of a multizone target assembly in an exemplary physical vapor deposition chamber.

FIG. 3C illustrates the composite profile of a voltage delivered to target sections 127A-B as a function of time as shown in FIGS. 3D and 3E.

FIG. 3D illustrates a voltage that is delivered to a target section 127A as a function of time.

FIG. 3E illustrates a voltage that is delivered to a target section 127B as a function of time.

FIG. 3F illustrates the composite profile of a voltage delivered to target sections 127A-B as a function of time as shown in FIGS. 3G and 3H.

FIG. 3G illustrates a voltage that is delivered to a target section 127A as a function of time.

FIG. 3H illustrates a voltage that is delivered to a target section 127B as a function of time.

FIG. 4A is a vertical cross-sectional view of a processing region formed in an exemplary physical vapor deposition chamber.

FIG. 4B is a vertical cross-sectional view of a processing region formed in an exemplary physical vapor deposition chamber.

FIG. 4C illustrates the target sections of a multizone target assembly in an exemplary physical vapor deposition chamber.

FIG. 4D illustrates a plot of magnetic field strength versus the distance along a path that extends across and through the center of a multizone target assembly that may be used in an exemplary physical vapor deposition chamber.

FIG. 4E illustrates the target sections of a multizone target assembly in an exemplary physical vapor deposition chamber.

FIG. 4F illustrates a plot of magnetic field strength versus the distance along a path that extends across and through the center of a multizone target assembly that may be used in an exemplary physical vapor deposition chamber.

FIG. 4G illustrates the target sections of a multizone target assembly in an exemplary physical vapor deposition chamber.

FIG. 4H illustrates a plot of magnetic field strength versus the distance along a path that extends across and through the center of a multizone target assembly that may be used in an exemplary physical vapor deposition chamber.

FIG. 5A illustrates a plan view of one embodiment of the multizone target assembly illustrated in FIG. 2 that contains two target sections.

FIG. 5B illustrates a plan view of one embodiment of the multizone target assembly illustrated in FIG. 2 that contains two target sections that are formed from multiple tiles.

FIG. 5C illustrates a plan view of one embodiment of the multizone target assembly that contains five concentric target sections.

FIG. 5D illustrates a plan view of one embodiment of the multizone target assembly that contains seven target sections.

FIG. 6 is a vertical cross-sectional view of a processing region formed in an exemplary physical vapor deposition chamber.

FIG. 7A is a vertical cross-sectional view of a processing region formed in an exemplary physical vapor deposition chamber.

FIG. 7B illustrates a plan view of one embodiment of the multizone target assembly and process gas delivery assembly, which may useful to perform aspects of the invention disclosed herein.

FIG. 7C illustrates a plan view of one embodiment of the multizone target assembly and process gas delivery assembly, which may useful to perform aspects of the invention disclosed herein.

FIG. 7D illustrates a plan view of one embodiment of the multizone target assembly and process gas delivery assembly, which may useful to perform aspects of the invention disclosed herein.

FIG. 8 is a vertical cross-sectional view of a processing region formed in an exemplary physical vapor deposition chamber.

### DETAILED DESCRIPTION

The present invention generally provides an apparatus and method for processing a surface of a substrate in a PVD chamber that has a sputtering target that has separately biasable sections, regions or zones to improve the deposition uniformity. In general, aspects of the present invention can be used for flat panel display processing, semiconductor processing, solar cell processing, or any other substrate processing. The invention is illustratively described below in reference to a physical vapor deposition system, for processing large area substrates, such as a PVD system, available from AKT, a division of Applied Materials, Inc., Santa Clara, Calif. In one embodiment, the processing chamber is adapted to process substrates that have a processing surface surface area of at least about 2000 cm². In another embodiment, the processing chamber is adapted to process substrates that have a processing surface surface area of at least about 19,500 cm² (e.g., 1300 mm×1500 mm). In another embodiment, the processing chamber is adapted to process rectangular substrates. However, it should be understood that the apparatus and method may have utility in other system configurations, including those systems configured to process large area round substrates.

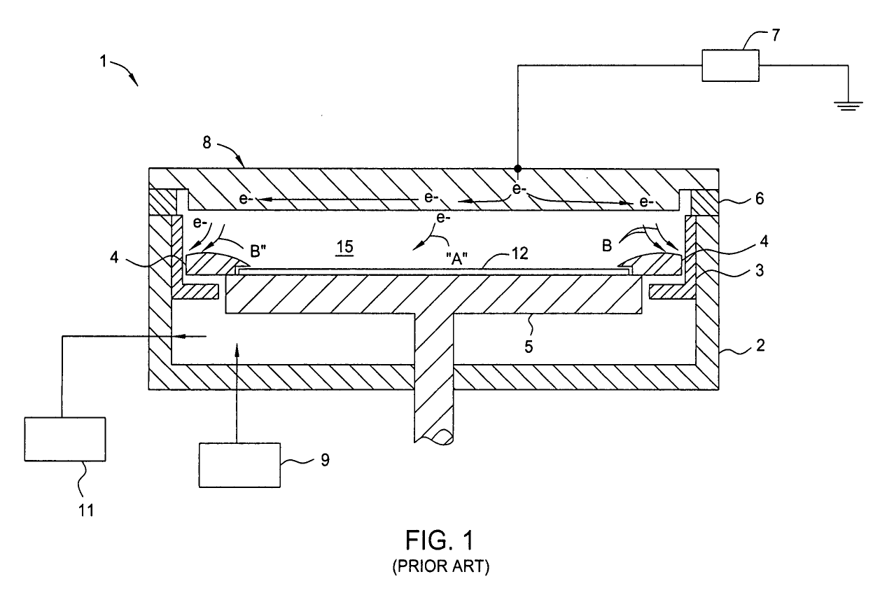

FIG. 1 illustrates a cross-sectional view of the processing region of a conventional physical vapor deposition (PVD) chamber 1. The conventional PVD chamber 1 generally contains a target 8, a vacuum chamber 2, a anode shield 3, a shadow ring 4, an target electrical insulator 6, a DC power supply 7, a process gas source 9, a vacuum pump system 11 and a substrate support 5. To perform a sputtering process, a process gas, such as argon, is delivered into the evacuated conventional PVD chamber 1 from the gas source 9 and a plasma is generated in the processing region 15 due to a negative bias created between the target 8 and the anode shield 3 by use of the DC power supply 7. In general, the plasma is primarily generated and sustained by the emission of electrons from the surface of the target due to the target bias and secondary emission caused by the ion bombardment of the negative (cathodic) target surface. Prior to performing the PVD processing step(s) it is common for the vacuum chamber 2 to be pumped down to a base pressure (e.g., 10⁻⁶ to 10⁻⁹ Torr) by use of the vacuum pump system 11.

FIG. 1 is intended to illustrate one of the believed causes of the plasma non-uniformity in a large area substrate processing chamber by highlighting the path difference between the an electron (see e⁻) ejected from the surface of the target 1 near the center of the target (see path “A”) and electrons emitted from the surface of the target (e.g., secondary emission) near the edge (see path “B”). While the longer path to the anode, typically a grounded surface, experienced by an electron leaving the center of the target may increase the number of collisions the electron will undergo before it is lost to the anode surface or recombined with an ion contained in the plasma, the bulk of the electrons emitted from the target 8 will be emitted near the edge of the target due to the reduced electrical resistance of this path to ground. The reduced electrical resistance of the path near the edge of the target to ground is due to the lower resistance path through the conductive target 8 material(s) and the shorter path length (“B”) of the electron's path to ground. It is believed that the lower resistance path thus tends to increase the current density and plasma density near the edge of the target thus increasing the amount of material sputtered at the edge versus the center of the target 1.

Target Assembly Hardware

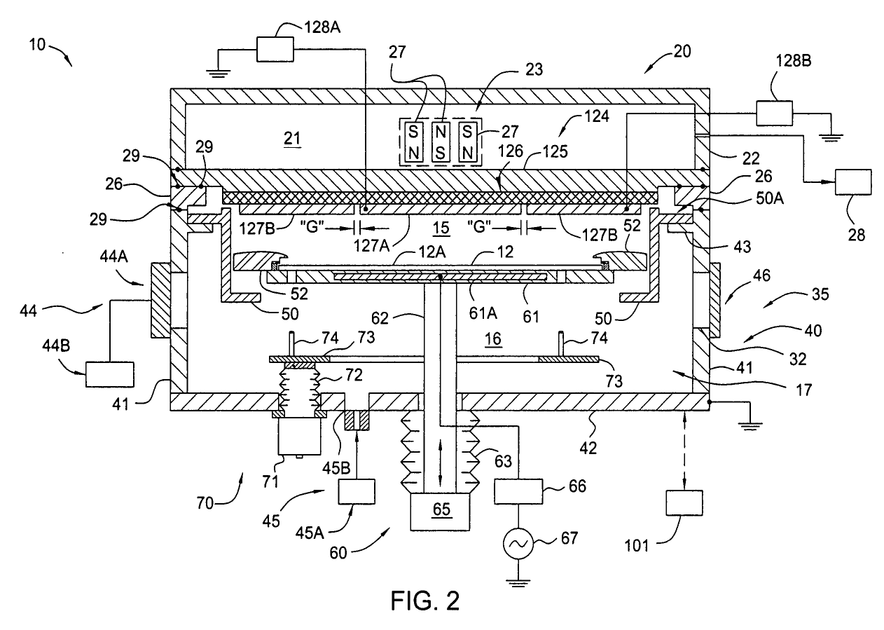

FIG. 2 illustrates a vertical cross-sectional view of one embodiment of a processing chamber 10 that may be used to perform aspects of the invention described herein. In general, the various embodiments described herein utilize a multizone target assembly 124 that is used to generate a plasma of varying density in the processing region 15 of the processing chamber 10 by separately biasing different target sections 127 (elements 127A and 127B in FIG. 2) to achieve a desired sputter deposition profile across the substrate surface. Referring to FIG. 2, the processing region 15 is generally the region formed between the multizone target assembly 124, a surface of a substrate 12 positioned on the substrate support 61, and the shield 50. The term sputter deposition profile is intended to describe the deposited film thickness as measured across the substrate processing surface (element 12A). In one aspect, the sputter deposition profile is adjusted by tailoring the plasma density profile throughout the processing region 15, by varying the voltage applied to the target sections. FIG. 2 illustrates one embodiment of the multizone target 124 that contains two target sections 127 (e.g., elements 127A and 127B). FIG. 2 also illustrates a substrate 12 that is positioned in a processing position in the processing region 15. In one aspect, the target sections 127 are generally made from the same or similar materials, which are to be sputter deposited on the processing surface 12A of the substrate 12. Typical elements or materials that the target sections may contain include, but are not limited to molybdenum, aluminum, aluminum neodymium alloys, copper, titanium, tantalum, tungsten, chromium, indium tin oxide, zinc, or zinc oxide. Thus, in one aspect, the target sections are made from metals that are doped, or alloyed, with a number of different components, such as a zinc material that is doped the elements aluminum (Al), silicon (Si), and/or gallium (Ga), or a copper material that is doped the elements indium (In), gallium (Ga), and/or selenium (Se).

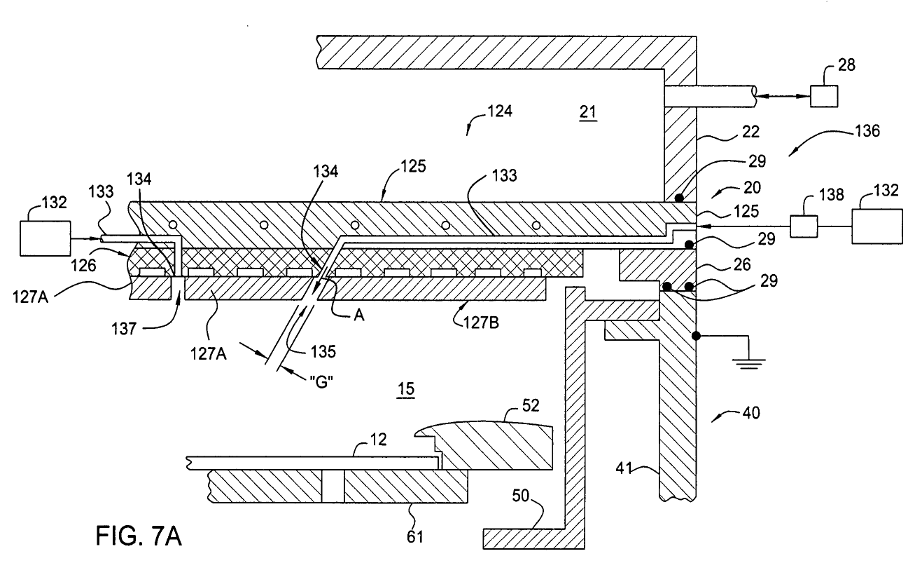

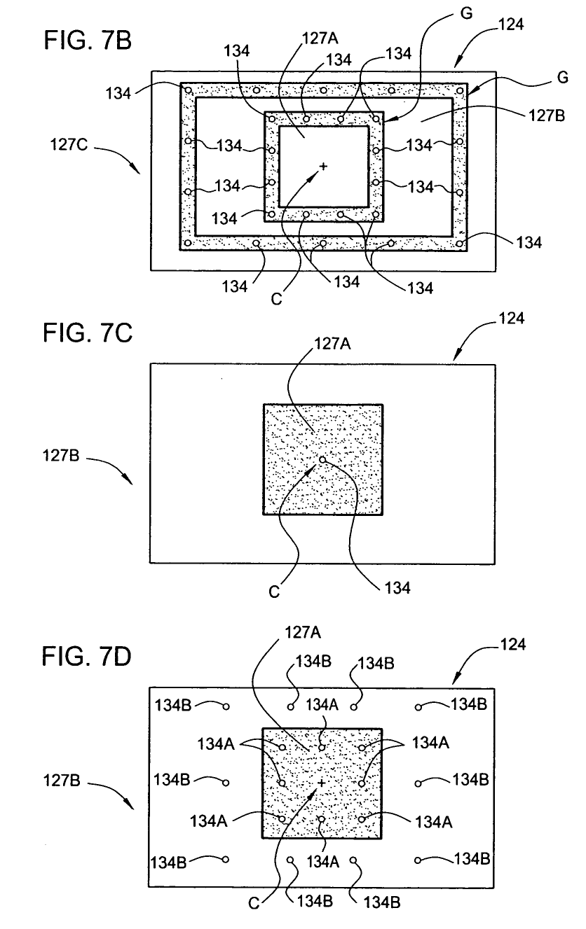

In general, the processing chamber 10 contains a lid assembly 20 and a lower chamber assembly 35. The lower chamber assembly 35 generally contains a substrate support assembly 60, chamber body assembly 40, a shield 50, a process gas delivery system 45 and a shadow frame 52. The shadow frame 52 is generally used to shadow the edge of the substrate to prevent or minimize the amount of deposition on the edge of a substrate 12 and substrate support 61 during processing (see FIG. 2). The chamber body assembly 40 generally contains one or more chamber walls 41 and a chamber base 42. The one or more chamber walls 41, the chamber base 42 and a surface of the multizone target assembly 124 generally form a vacuum processing area 17 that has a lower vacuum region 16 and a processing region 15. In one aspect, a shield mounting surface 50A of the shield 50 is mounted on or connected to a grounded chamber shield support 43 formed in the chamber walls 41 to ground the shield 50. In one aspect, the process chamber 10 contains a process gas delivery system 45 that has one or more gas sources 45A that are in fluid communication with one or more inlet ports 45B that are used to deliver a process gas to the vacuum processing area 17. In one aspect, discussed below in conjunction with FIG. 7A, the process gas could be delivered to the processing region 15 through the multizone target assembly 124. Process gases that may be used in PVD type applications are, for example, inert gases such as argon or other reactive type gases such as nitrogen or oxygen containing gas sources. In one embodiment, the substrate support 61 may contain RF biasable element 61A embedded within the substrate support 61 that can be used to capacitively RF couple the substrate support 61 to the plasma generated in the processing region 15 by use of an RF power source 67 and RF matching device 66. The ability to RF bias the substrate support 61 may be useful to help improve the plasma density, improve the deposition profile on the substrate, and increase the energy of the deposited material at the surface of the substrate.

The substrate support assembly 60 generally contains a substrate support 61, a shaft 62 that is adapted to support the substrate support 61, and a bellows 63 that is sealably connected to the shaft 62 and the chamber base 42 to form a moveable vacuum seal that allows the substrate support 61 to be positioned in the lower chamber assembly 35 by the lift mechanism 65. The lift mechanism 65 may contain a conventional linear slide (not shown), pneumatic air cylinder (not shown) and/or DC servo motor that is attached to a lead screw (not shown), which are adapted to position the substrate support 61, and substrate 12, in a desired position in the processing region 15.

Referring to FIG. 2, the lower chamber assembly 35 will also generally contain a substrate lift assembly 70, slit valve 46 and vacuum pumping system 44. The lift assembly 70 generally contains three or more lift pins 74, a lift plate 73, a lift actuator 71, and a bellows 72 that is sealably connected to the lift actuator 71 and the chamber base 42 so that the lift pins 74 can remove and replace a substrate positioned on a robot blade (not shown) that has been extended into the lower chamber assembly 35 from a central transfer chamber (not shown). The extended robot blade enters the lower chamber assembly 35 through the access port 32 in the chamber wall 41 and is positioned above the substrate support 61 that is positioned in a transfer position (not shown). The vacuum pumping system 44 (elements 44A and 44B) may generally contain a cryo-pump, turbo pump, cryo-turbo pump, rough pump, and/or roots blower to evacuate the lower vacuum region 16 and processing region 15 to a desired base and/or processing pressure. A slit valve actuator (not shown) which is adapted to position the slit valve 46 against or away from the one or more chamber walls 41 may be a conventional pneumatic actuator which are well known in the art.

To control the various processing chamber 10 components, power supplies 128, gas supplies, and process variables during a deposition process, a controller 101 is used. The controller 101 is typically a microprocessor-based controller. The controller 101 is configured to receive inputs from a user and/or various sensors in the plasma processing chamber and appropriately control the plasma processing chamber components in accordance with the various inputs and software instructions retained in the controller's memory. The controller 101 generally contains memory and a CPU which are utilized by the controller to retain various programs, process the programs, and execute the programs when necessary. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like all well known in the art. A program (or computer instructions) readable by the controller 101 determines which tasks are performable in the plasma processing chamber. Preferably, the program is software readable by the controller 101 and includes instructions to monitor and control the plasma process based on defined rules and input data.

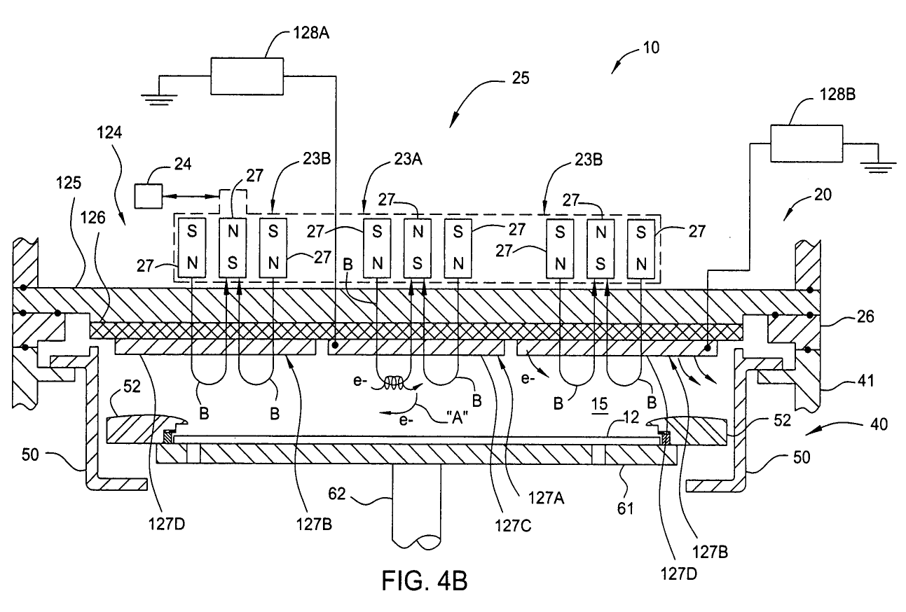

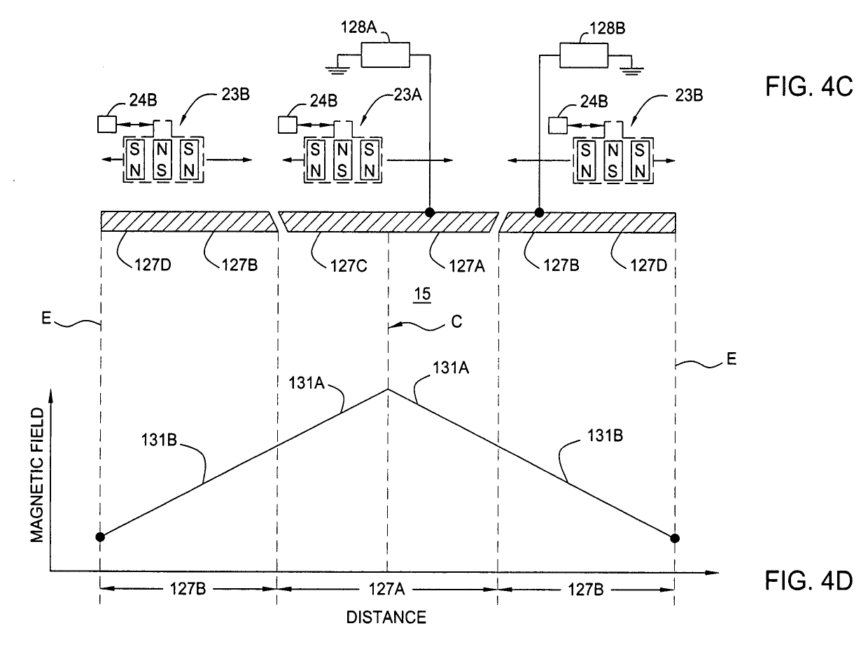

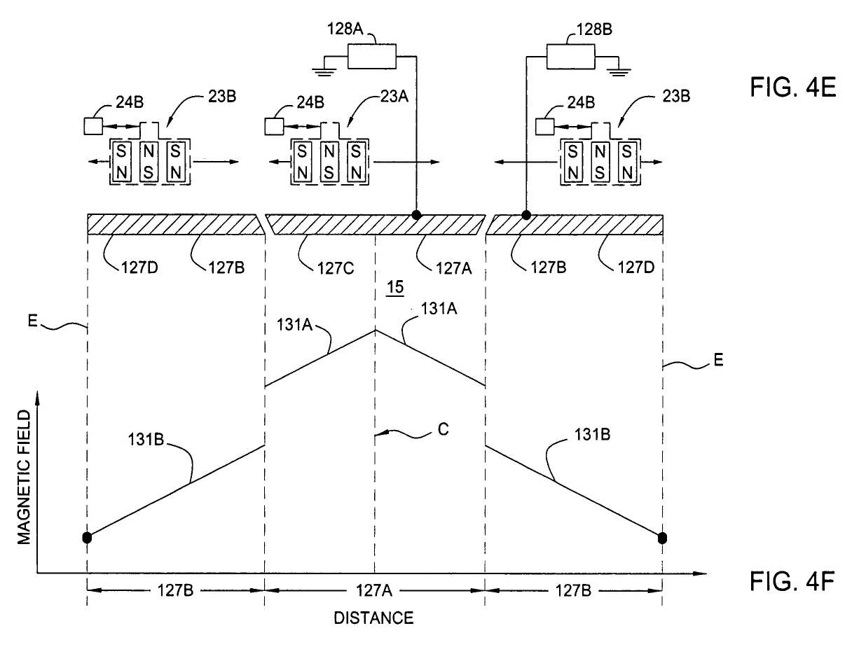

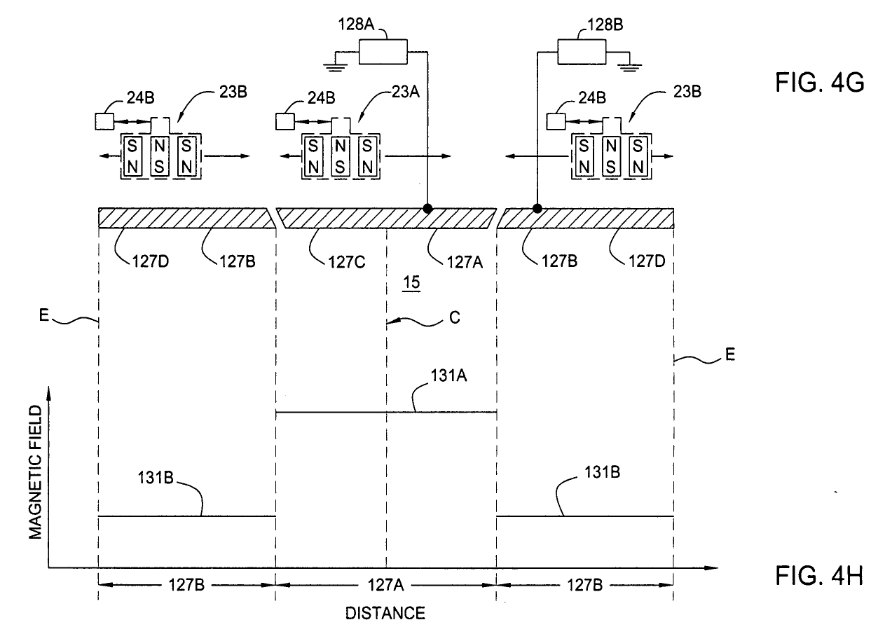

The lid assembly 20 generally contains a multizone target assembly 124, a lid enclosure 22, a ceramic insulator 26, one or more o-ring seals 29 and one or more magnetron assemblies 23 that are positioned in a target backside region 21. In one aspect, the ceramic insulator 26 is not required to provide electrical isolation between the backing plate 125 of the multizone target assembly 124 and the chamber body assembly 40. Generally, each magnetron assembly 23 will have at least one magnet 27 that has a pair of opposing magnetic poles (i.e., north (N) and south (S)) that create a magnetic field (B-field) that passes through the multizone target assembly 124 and the processing region 15 (see element “B” in FIGS. 4A-B). FIG. 2 illustrates a vertical cross-section of one embodiment of a processing chamber 10 that has one magnetron assembly 23 that contain three magnets 27, which are positioned in the target backside region 21 at the back of the multizone target assembly 124. An exemplary magnetron assembly, that may be adapted to benefit the invention described herein, is further described in the commonly assigned U.S. patant application Ser. No. 10/863,152 [AMAT 8841], filed Jun. 7, 2004, which claims the benefit of U.S. Provisional Patent Application Ser. No. 60/534,952, filed Jan. 7, 2004, and is hereby incorporated by reference in its entirety to the extent not inconsistent with the claimed invention.

To perform a PVD deposition process, the controller 101 commands the vacuum pumping system 44 to evacuate the processing chamber 10 to a predetermined pressure/vacuum so that the plasma processing chamber 10 can receive a substrate 12 from a system robot (not shown) mounted to a central transfer chamber (not shown) which is also under vacuum. To transfer a substrate 12 to the processing chamber 10 the slit valve (element 46), which seals off the processing chamber 10 from the central transfer chamber, opens to allow the system robot to extend through the access port 32 in the chamber wall 41. The lift pins 74 then remove the substrate 12 from the extended system robot, by lifting the substrate from the extended robot blade (not shown). The system robot then retracts from the processing chamber 10 and the slit valve 46 closes to isolate the processing chamber 10 from the central transfer chamber. The substrate support 61 then lifts the substrate 12 from the lift pins 74 and moves the substrate 12 to a desired processing position below the multizone target assembly 124. Then after a achieving a desired base pressure, a desired flow of a processing gas is injected into the processing region 15 and a bias voltage is applied to at least one of the target sections 127 of the multizone target assembly 124 by use of a power supply (elements 128A-B) attached to the target section that is to be biased. The application of a bias voltage by the power supply causes ionization and dissociation of the gas in the processing region 15 and the generated ions subsequently bombard the surface of the cathodically biased target section(s) 127 and thus “sputter” the target atoms from the target surface. A percentage of the “sputtered” target atoms then land on the surface of the substrate positioned on the surface of the substrate support 61. The ion energy and ion flux near the target sections 127, which is related to the magnitude of the bias voltage applied to each of the biased target sections, can thus be tailored to assure a uniform or desired distribution is achieved throughout the processing region. One will note that each target section 127 that is not biased can either be electrically floating or be grounded. In either case, generally no sputtering activity will occur on these target sections during this process step. It should be noted that the term “grounded” as used herein is generally intended to describe a direct or in-direct electrical connection between a component that is to be “grounded” and the anode surfaces (e.g., element 50) positioned inside the processing chamber 10.

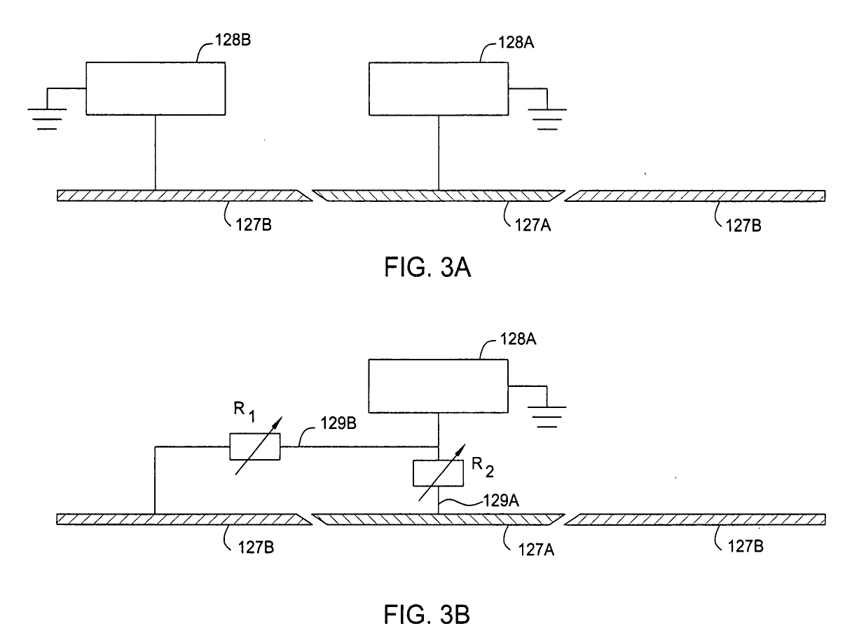

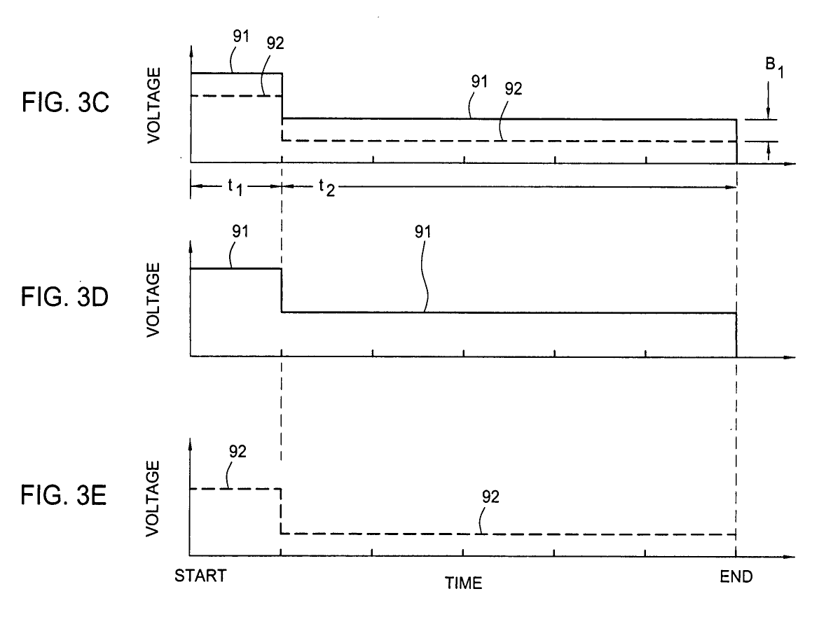

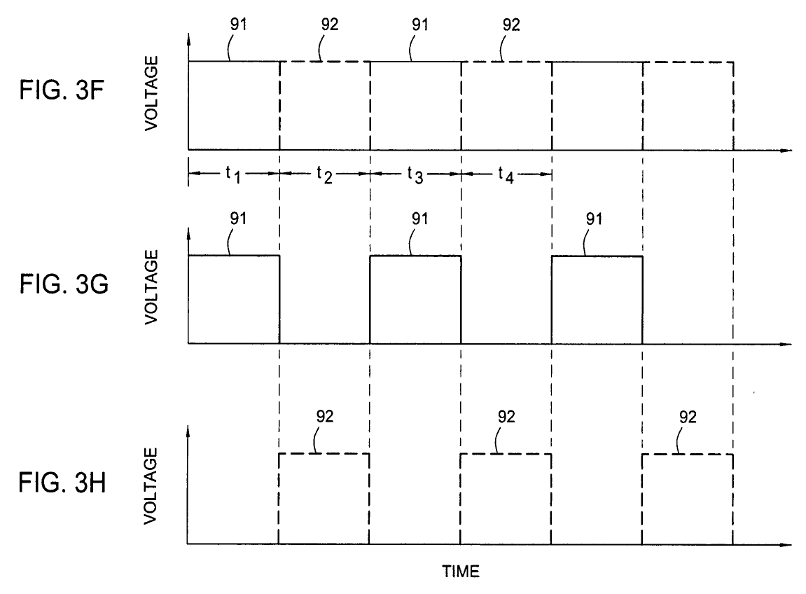

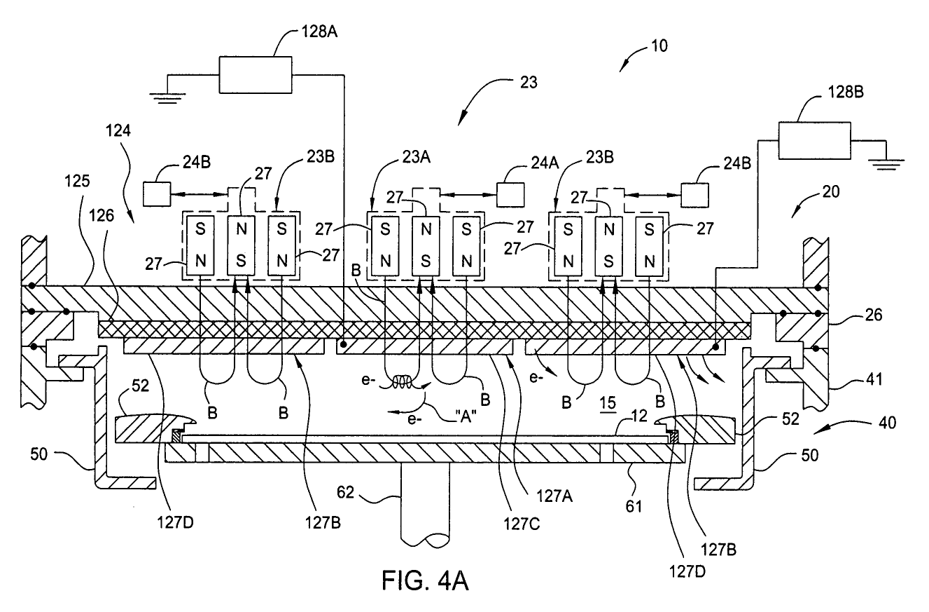

FIGS. 3A and 3B illustrate a simplified schematic of two embodiments that may be used to separately electrically bias the various target sections 127. FIG. 2 illustrates a multizone target assembly 124 that has two sections 127A-B that can be separately biased by use of two different power supplies 128A-B. The ability to bias the target sections 127 at different voltage levels is used to adjust and improve the plasma density uniformity in the processing region 15 and thus deposition profile across the substrate surface. In one aspect, the difference in voltage applied between the various target sections 127 at any given time may be between about 10 and about 400 volts, and preferably between about 50 and about 200 volts. It should be noted that the optimal biasing voltage applied to each target section 127 may vary depending on the process pressure in the processing region 15 and type of process gases (e.g., argon) used during processing. In one embodiment, the power supplies (elements 128A-B) are DC power supplies that are adapted to deliver a cathodic or anodic bias to their respective target section 127 between about 1 millivolt and about 1000 volts at a power between about 0 and about 500 kWs. In another embodiment, one or more of the power supplies are an RF power source that is adapted to deliver a power between about 0 and about 500 kWs at a frequency between about 500 Hz to greater than 10 GHz.

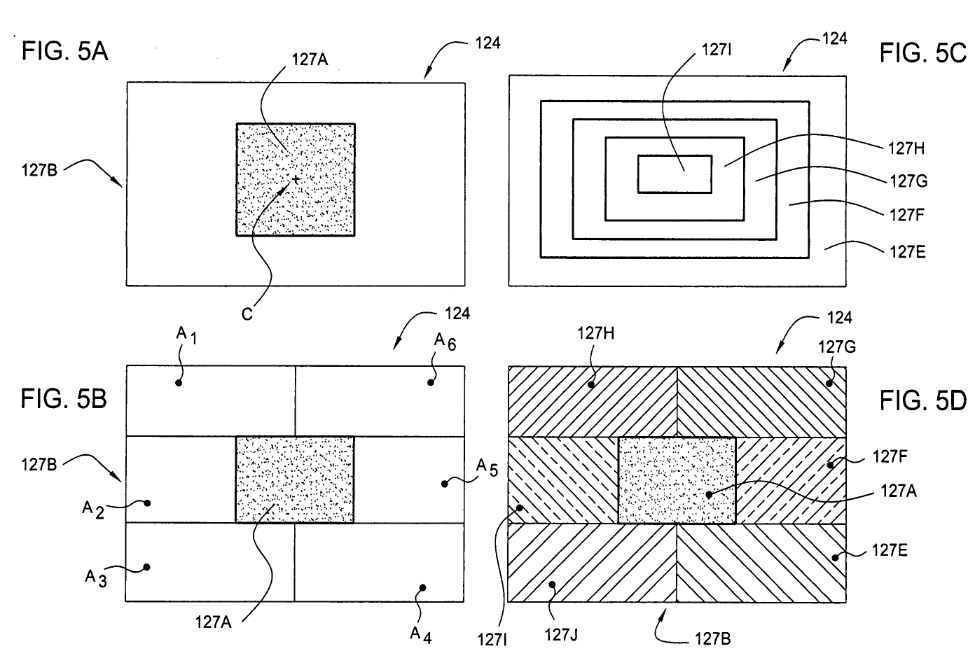

FIGS. 3B illustrates one embodiment in which each of the target zones, for example 127A and 127B, are biased at a different potential by use of a single power supply. In this configuration the amount of bias that can be applied may be varied by the introduction of resistive, capacitive and/or inductive components (elements R₁, and R₂) to the electrical connections (elements 129A-B) between the various target sections. In one aspect, elements R₁ and/or R₂ contain a variable resistor, a variable capacitor and/or a variable inductor that are controlled by the controller 101 to adjust the bias voltage and/or current delivered to one or more of the target sections 127. One will note that while FIGS. 2, 3A-B and 4A-F illustrate an embodiment that has two concentric target sections 127 (see FIGS. 5A-B), this configuration is not intended to be limiting and thus other configurations that utilize a non-concentric orientation, or that have more than two zones, may be utilized to achieve a desired sputter deposition profile without varying from the basic scope of the invention as described herein.

FIGS. 3C-H illustrate various .embodiments of the invention where the magnitude of the voltage, or power, delivered to the target sections 127 of a multizone target assembly 124 may be varied as a function of time by use of the controller 101. While FIGS. 3C-H illustrate different methods of modulation of the voltage applied to two target sections 127, other embodiments of the invention may contain more than two target sections 127.

FIG. 3C illustrates the composite profile of the voltage applied to the target sections, for example 127A and 127B in FIG. 2, as a function of time by use of the controller 101. The voltage waveform delivered to the target section 127A and target section 127B are shown in FIGS. 3D and 3E, respectively. The voltage waveform 91 in FIG. 3D illustrates an embodiment of a voltage profile delivered to the target section 127A as a function of time. The voltage waveform 92 in FIG. 3E illustrates an embodiment of a voltage profile delivered to target section 127B as a function of time. FIGS. 3C-E illustrate a case where the voltage in the processing chamber is kept relatively constant as a function of time throughout the PVD deposition process. In one aspect, as shown in FIGS. 3C-E, a high cathodic ignition voltage (e.g., >600V) is applied for a time t₁ to the target sections 127A and 127B so that a plasma is formed in the processing region 15. Generally, the time t₁ to ignite a plasma is on the order of milliseconds or microseconds. After the plasma is formed in the processing region 15, a processing bias is applied to the various target sections at a desired magnitude for a desired period of time t₂ to achieve a desired deposition thickness, deposition rate and deposition uniformity on the substrate. In one aspect, as shown in FIGS. 3C, a differential bias B₁. may be applied to target section 127A that is larger than the bias applied to the target section 127B, to achieve a desired plasma density distribution across the multizone target assembly 124 and thus deposition profile across the substrate. In one example, the differential bias B₁. applied between the various target sections 127 at any given time may be between about 10 and about 400 volts. It should be noted that the magnitude of the differential bias B₁. is strongly dependent on the size of the substrate, the process pressure, and the magnitude of the bias voltages applied to the target sections.

FIG. 3F illustrates the composite profile of rectangular-shaped biasing pulses that may delivered to the target sections 127A and 127B (FIG. 2) as a function of time by use of the controller 101. The rectangular-shaped biasing pulses delivered to the target sections 127A and 127B are shown in FIGS. 3G and 3H, respectively. The modulated bias pulse waveform 91 in FIG. 3G illustrates an embodiment of an amplitude modulation of the voltage delivered to a target section 127A as a function of time. The modulated bias pulse waveform 92 in FIG. 3H illustrates an embodiment of an amplitude modulation of the voltage delivered to a target section 127B as a function of time. FIGS. 3F-3H illustrate a case where the total power in the processing chamber is kept relatively constant as a function of time but the power to each target section is either on or off at any given time, except possibly during the transition to or from the peak voltage level. In one embodiment, the peak bias level, pulse width (e.g., elements t₁, t₂, t₃, t₄), and modulation bias pulse frequency (e.g., number of pulses per unit time) of each bias pulse applied to the target sections may be varied from one pulse to the next. In other embodiments, the biasing pulse(s) applied to the target sections 127 are not rectangular in shape, as shown in FIG. 3F-H, and may be, for example, trapezoidal, triangular, saw tooth, etc. in shape. The pulse frequency may be between about 1 and about 1000 Hertz (Hz) and preferably between about 10 and about 500 Hz. In one aspect, for large area substrates it is desirable to increase the bias pulse width for the central target sections (e.g., elements t₁ and t₃) versus the edge target sections (e.g., elements t₂ and t₄) to help improve the deposition uniformity from center to edge. In other embodiments, the frequency (or period) of the biasing pulse delivered to the two or more target sections may be varied throughout the deposition process, from one pulse to another, or as different processing conditions are varied. In still other embodiments, the amount of power delivered for each subsequent biasing pulse may not be equal and may be varied throughout the plasma process, from one biasing pulse to another, or as different processing conditions are varied.

Magnetron Design For Processing

FIG. 4A illustrates a close up view of the processing region 15 and lid assembly 20 of one embodiment of the process chamber 10. The embodiment illustrated in FIG. 4A has a lid assembly 20 that has a multizone target assembly 124 and at least one magnetron assembly 23 positioned adjacent to each of the target sections 127 of the multizone target assembly 124. Typically, to improve utilization of the target material and improve deposition uniformity it is common to translate (e.g., raster, scan, and/or rotate) each of the magnetron assemblies in at least one of the directions that are parallel to the target surface (elements 127C-D) by use of one or more magnetron actuators (elements 24A and 24B). The magnetron actuator(s) may be a linear motor, stepper motor, or DC servo motor that are adapted to position and move the magnetron assembly in a desired direction at a desired speed by use of commands from the controller 101. A translation mechanism used to move the magnetron, along with magnet orientations in the magnetron assembly, that may be adapted to benefit the invention described herein is further described in the commonly assigned U.S. patent application Ser. No. 10/863,152 [AMAT 8841], filed Jun. 7, 2004, which claims the benefit of U.S. Provisional Patent Application Ser. No. 60/534,952, filed Jan. 7, 2004, and is hereby incorporated by reference in its entirety to the extent not inconsistent with the claimed invention.

During the PVD deposition process a large portion of the generated plasma in the processing region 15 is formed and is retained below the magnetron assemblies 23 due to the magnetic fields (elements “B”) containment of the electrons found in the processing region 15. The optimum magnetic field profile for a processing chamber 10 will vary from one substrate size to another, from the ratio of the anode (e.g., grounded surface) to cathode (e.g., target) surface area, target to substrate spacing, PVD process pressure, motion of the magnetron across the target face, desired deposition rate, and type of material that is being deposited. The effectiveness of the magnetron 23 on reducing the center to edge deposited thickness variation is affected by the magnetic permeability of the target material(s). Therefore, in some case the magnetron magnetic field pattern may need to be adjusted based on the type of multizone target assembly 124 material(s) and their thickness(es).

The magnetron assembly 23 has an effect on the shape and uniformity of the PVD deposited layer due to the strength and orientation of the magnetic fields generated by the magnetron assembly 23. In general, each of the magnetron assemblies 23 (elements 23A-B) will contain at least one magnet 27. The magnets 27 may be permanent magnets (e.g., neodymium, samarium-cobalt, ceramic, or Alnico) or electromagnets. FIG. 4B illustrates another embodiment of the processing chamber 10 which contains a single magnetron assembly 25 that extends across the target sections (elements 127A-B) and delivers a constant or varying magnetic field strength across the multizone target assembly 124. In this configuration the single magnetron assembly 25 may contain two or more regions (elements 23A-B) that have differing magnetic field strengths that are optimized to achieve a desired plasma density and sputter deposition profile. The single magnetron assembly 25 may be rotated, scanned, and/or translated across the multizone target assembly 124 to improve the utilization of the target material and improve deposition uniformity, by use of a magnetron actuator 24.

Referring to FIG. 4A and FIGS. 4C-H, in one embodiment of the processing chamber 10, the one or more magnetron assemblies 23 are distributed across the multizone target assembly 124 to balance out the difference in current flow between the center and edge of the target caused the differing resistance to the anode (e.g., ground) for each of these paths. The control of the magnetic field distribution from the center to the edge of the multizone target assembly 124 is used to control and improve plasma density and thus the deposition uniformity across the processing surface, which is positioned near the surface of the target sections (elements 127C-D). In one aspect, the magnetic field strength of the magnetron assemblies 23 is configured to deliver a higher magnetic field strength in the target sections (e.g., element 127A FIG. 4A) near the center rather than at the edge of the multizone target. FIGS. 4C, 4E and 4G schematically illustrate a multizone target assembly 124 that has two or more magnetron assemblies (elements 23A-B) that are each adapted to primarily control the magnetic field in their target section 127 (e.g., element 127A or 127B) during processing. Referring to FIG. 4C, 4E and 4G, the magnetron assembly 23A is thus adapted to control the magnetic field strength throughout the target section 127A and the magnetron assembly 23B, or magnetron assemblies 23B, are adapted to control the magnetic field strength throughout the target section 127B. The magnetic field strength can be adjusted in each of target sections by use of stronger magnets in different regions of the magnetron assembly 23, increasing the density of the magnets in different regions of the magnetron, positioning additional stronger stationary magnets over certain sections of the multizone target assembly 124, using electromagnets that allow one to adjust the delivered magnetic field and/or increasing the dwell time over the certain areas of the target section(s) as the magnetron is translated during processing by use of the magnetron actuators 24.

In one aspect, each of the magnetron assemblies 23A or 23B are adapted to translate across the target section(s) 127 in unison by use of magnetron actuator(s) (elements 24A-B in FIG. 4A and element 24 in FIG. 4B) to control plasma density uniformity and improve the deposition profile across the substrate surface. In another aspect, each of the magnetron assemblies 23A or 23B are adapted to separately translated across the target sections 127 by use of one or more magnetron actuators (element 24A-B FIG. 4A). In one aspect, it may be desirable to limit the translation of the magnetron assemblies to positions that minimize the interaction with the other target sections 127 and magnetron assemblies 23 to improve the deposition uniformity profile across the substrate.

Referring to FIG. 4C, 4E and 4G, in one embodiment, the magnets 27 in the magnetron assemblies (elements 23A and 23B) are electromagnets that may be translated or remain stationary over the target section(s) during processing. In one aspect, the magnetic field (B-Field) generated by the electromagnets can be dynamically adjusted during different phases of the deposition process, by adjusting the current passing through the plurality conductive coils contained in the electromagnet.

In another aspect of the process chamber 10, the magnetic field generated by the electromagnets (element 27) can be dynamically adjusted as a function of position of the magnetron assembly 23 over its target section 127. For example, the magnetron assembly's magnetic field strength may be reduced as magnetron assembly 23 is translated to positions that are near an edge of a target section 127 to reduce the interaction between the adjacent target sections or other chamber components. The ability to adjust the magnetic field strength as a function of translational position can help to improve the deposition uniformity and reduce the interaction between the various target sections.

FIGS. 4D, 4F and 4H illustrate a plot of magnitude of the magnetic field as a function of linear distance across each section of the multizone target assembly 124. The magnetic field strength in these plots may be generated by the static placement of magnets across the target sections, the time average of the magnetic field strength caused by the translation of the magnetron assemblies 23 across the target sections 127 in the multizone target assembly 124, and/or the varying of the magnetic field strength by adjusting the current delivered to the one or more electromagnets that are distributed across the each of the target sections 127. The plots shown in FIGS. 4D, 4F and 4H illustrate the magnitude of the magnetic field in a linear path that extends from one edge of the multizone target assembly 124 through the center point of the multizone target assembly 124 and out to the opposite edge of the multizone target assembly 124.

FIG. 4D illustrates an exemplary distribution of the magnetic field strength (elements 131A-B) across the multizone target assembly (see FIG. 4C) measured just below the target surfaces 127C-D in the processing region 15. As shown the magnetic field strength varies linearly from the edge (element “E”) of the multizone target assembly 124 and peaks at the center (element “C”) of the multizone target assembly 124. In this configuration the larger magnetic field strength in the center target section 127A will tend to increase the plasma density in the center versus the edge of the multizone target assembly 124 and thus can be used to improve the sputter deposition profile when used in large area substrate processing chambers. In one example, the magnetic field strength variation from the center of the target to the edge for a process chamber adapted to process a 2.2 m×2.5 m substrate is configured to deliver about 0 to about 500 gauss near the edge to about 300 to about 1000 gauss near the center of the multizone target assembly 124.

FIG. 4F illustrates an exemplary distribution of the magnetic field strength (elements 131A-B) across the multizone target assembly (see FIG. 4E) measured just below the target surfaces 127C-D in the processing region 15. As shown in FIG. 4F the magnetic field strength varies linearly in each of the target sections 127A-B, but the magnetic field strength has a discontinuity at the transitions between the target sections (elements 127A and 127B). In this configuration the larger magnetic field strength in the center target section 127A will tend to increase the plasma density in the center versus the edge of the multizone target assembly 124 and thus can be used to improve the deposition profile.

FIG. 4H illustrates an exemplary distribution of the magnetic field strength (elements 131A-B) across the multizone target assembly (see FIG. 4G) measured just below the target surfaces 127C-D in the processing region 15. As shown in FIG. 4F the magnetic field strength is constant in each of the target sections 127A-B, but the magnetic field strength has a discontinuity at the transitions between the target sections (elements 127A and 127B). In this configuration the larger magnetic field strength in the center target section 127A will tend to increase the plasma density in the center versus the edge of the multizone target assembly 124 and thus can be used to improve the deposition profile.

Referring to FIGS. 4D, 4F and 4H, while the graphs of magnetic field strength across the multizone target assembly 124 are shown to vary in a linear fashion from the center to the edge of the target, other embodiments of the invention may use second degree (e.g., quadratic), third degree (e.g., cubic), exponential, or other shaped curves that delivers a desired the plasma density across the target face and desired sputter deposition profile without deviating from the basic scope of the invention described herein. Also, while FIGS. 4D, 4F and 4H illustrate the magnetic field strength across the multizone target assembly 124, which peak at the center (“C”) of the target assembly 124, this configuration is not intended to be limiting to basic scope of the invention. Furthermore, while FIGS. 4D, 4F and 4H illustrate a magnetic field strength plot that varies in two main target sections (e.g., center and edge), other configurations may be used that contain an optimized magnetic field strength profile that contains multiple segments of changing magnetic field strength without varying form the basic scope of the invention as described herein.

Target sections

FIG. 5A illustrates a plan view of one embodiment of the multizone target assembly 124 illustrated in FIG. 2 that contains two target sections 127A and 127B. In this configuration, each of the target sections 127A-B are formed from a single continuous piece of target material that will be sputter deposited onto the substrate surface. In one aspect, the each of the target sections are formed from the same type of material so that deposited film will have a uniform thickness and composition across the substrate surface. In one embodiment, as shown in FIG. 5A, a first target region 127A is “surrounded” by a second target region 127B. The term “surrounded” as used herein is intended to describe a positional orientation in at least one plane where a first target region is positioned within or encircled by a second target region. In another embodiment of the multizone target assembly 124, the target regions are “surrounded” and at least one axis of symmetry of a first target region 127A is coincident to an axis of symmetry of a second target region 127B. For example, the center point (element “C”) of each of the target sections (elements 127A and 127B) are coincident with each other. One will note that the shape and size of the target surfaces 127C-D (FIG. 2) of the target sections 127A-B, as illustrated in FIGS. 5A-D, is dependent on the size and dimensions of the substrate. In general, the total surface area of the target surfaces (e.g., 127C-D) will be larger than the surface area of the substrate to avoid deposition non-uniformities created by plasma non-uniformities at the edge of the multizone target assembly 124. In one aspect, when the multizone target assembly 124 is used to deposit a layer on a rectangular flat panel display substrate, or rectangular solar cell type substrate, the target sections 127 form an active target surface that extends at least a few centimeters past the edge of the substrate in each direction.

FIG. 5B illustrates a plan view of one embodiment of the multizone target assembly 124 illustrated in FIG. 2 that contains two target sections 127A and 127B. In the configuration shown in FIG. 5B, the outer target section 127B is formed from multiple “plates” (elements A₁-A₆), or “tiles,” that are generally made of the same target material. As flat panel display substrates are becoming larger (e.g., >19,500 cm²) it is becomes cost prohibitive and in some cases technically impossible to form a target from a single monolithic plate. Therefore, targets formed from multiple plates that are electrically connected to each other, by welding, conductive bonding to a conductive backing plate or electrical connections formed by use of discrete wires, may be used to form each target section 127. In one aspect, the multiple plates are welded together by use of an e-beam welding process, a laser welding process, arc welding process or other comparable process that can be used to join materials together. Examples of exemplary techniques and physical shapes that may be used to form various target sections 127 are further described in the U.S. patent application Ser. No. 10/888,383 [APPM 9309], filed Jul. 9, 2004 and U.S. patent application Ser. No. 11/158,270 [APPM 9309.P1], filed Jun. 21, 2005, which are incorporated by reference herein in their entirety to the extent not inconsistent with the claimed aspects and description herein. Although, FIG. 5B illustrates one embodiment in which the outer target section 127B is formed from multiple plates and the inner target is formed from a single plate, other embodiments of the invention may have more than one target section (e.g., element 127A), or even all target sections, formed from a plurality of electrically connected plates.

FIG. 5C illustrates a plan view of one embodiment of the multizone target assembly 124 that contains five concentric target sections 127E-I. In this configuration each target section can be separately biased at different potentials by use of a power supplies (not shown) attached to each target section. In one embodiment, one or more of the target sections 127 may be grounded while other target sections are biased. For example, target sections 127E, 127G and 127I may each biased at some desired voltage, while target sections 127F and 127H may be grounded.

FIGS. 5D illustrates a plan view of one embodiment of the multizone target assembly 124 that contains seven target sections 127A and 127E-J. In this configuration each target section can be separately biased at a different potential by use of a power supply (not shown) attached to each target section to improve the sputter deposition uniformity.

It should be noted that while FIGS. 2 and 4A-4B generally illustrate a multizone target assembly 124 that has target sections 127 that are in the same plane (e.g., horizontal plane) this configuration is not intended to be limiting as to the scope of the invention described herein. In one embodiment, the target section(s) near the center of the multizone target assembly are positioned a further distance from the surface of the substrate than the target section(s) near the edge of the multizone target assembly. In another embodiment, the target section(s) near the center of the multizone target assembly are positioned closer to the surface of the substrate than the target section(s) near the edge of the multizone target assembly. Also, it should be noted that while FIGS. 2 and 4A-4B generally illustrate a multizone target assembly 124 that has target sections 127 that have a surface (e.g., 127C and 127D) that is generally parallel to the substrate surface in contact with the processing region 15, other embodiments may orient at least part of one or more of the target sections such that they are not parallel to the substrate surface. Examples of shapes of the multizone target assembly surfaces (e.g., 127C and 127D) may include, for example, a convex or concave shape.

Multizone Target Assembly Hardware

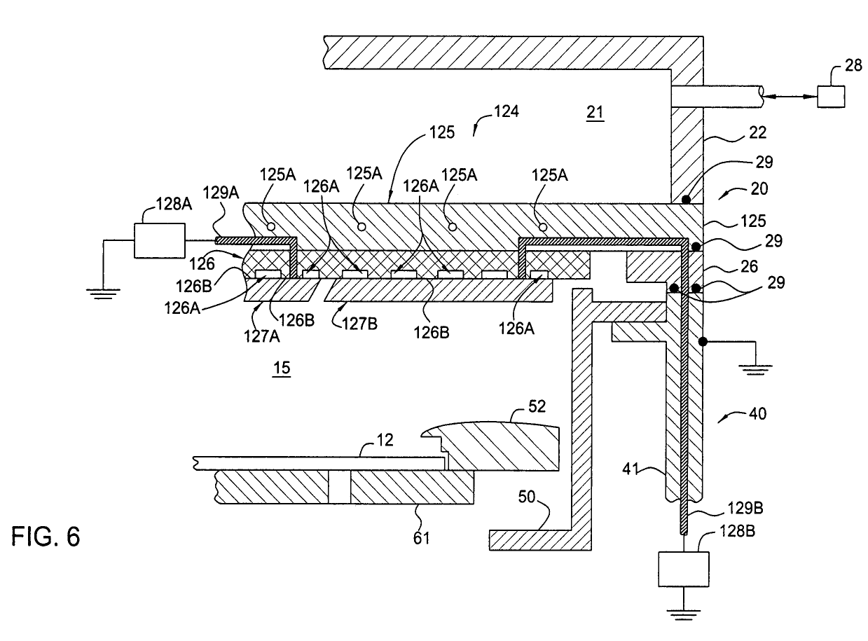

FIG. 6 illustrates a enlarged vertical cross-sectional view of one embodiment of the lid assembly 20 shown in FIG. 2. One will note that some of the elements shown in FIG. 6 are not shown in FIG. 2 for clarity reasons. The lid assembly 20, as shown in FIG. 6, generally contains a multizone target assembly 124, a lid enclosure 22, a ceramic insulator 26, one or more o-ring seals 29 and one or more magnetron assemblies 23 (FIG. 2). The multizone target assembly 124 generally contains a backing plate 125, an insulator 126, and two or more target sections 127 (e.g., elements 127A and 127B) that have a corresponding electrical connection (elements 129A and 129B) that connects each target section to its power supply (elements 128A-B) so that it can be biased during processing. In one aspect, the multizone target assembly 124 is electrically isolated from the electrically grounded chamber walls 41 of the chamber body assembly 40 by use of an insulator 26. This configuration may be useful to prevent or minimize arcing between the biased target sections 127 and the backing plate 125 during processing. In another aspect, the insulator 126 is removed to allow the backing plate 125 to be in electrical communication with the chamber body assembly 40 components.

In one aspect, the target sections 127 are electrically isolated from each other and supported by the insulator 126. In one aspect, the insulator 126 is made of an electrically insulative material, such as a ceramic material (e.g., aluminum oxide (Al₂O₃), aluminum nitride (AlN), quartz (SiO₂), Zirconia (ZrO)), a polymeric material (e.g., polyimide (Vespel®)) or other suitable material that may be able to structurally withstand the temperatures seen by the multizone target assembly 124 during processing. The thickness of the insulator 126 is sized to provide electrical isolation between the target sections 127 and between the target sections 127 and the backing plate 125. In one aspect, the target sections 127 are brazed or bonded by conventional means to the insulator 126 at a bonded region 126B. In another aspect, the target sections 127 are mechanically fastened (e.g., bolts) to the insulator 126 by conventional means.

In one aspect, the target sections 127 are actively cooled by use of heat exchanging channels 125A formed in the backing plate 125 to prevent the target sections 127 or braze or bonding materials used to form the bonded region 126B from being damaged by the temperatures achieved by the multizone target assembly 124 during processing. In this configuration the backing plate 125 is in thermal contact with the target sections 127 through the insulator 126, which is attached to the backing plate 125. In one aspect, the insulator 126 is brazed, bonded or mechanically fastened to the backing plate 125 by conventional means to improve the thermal heat transfer between the insulator 126 and the backing plate 125. The heat exchanging channels 125A are in fluid communication with a primary heat exchanging device (not shown) that is adapted to deliver a heat exchanging fluid (e.g., DI water, perfluoropolyethers (e.g., Galden®)) at a desired temperature and flow rate through them. The backing plate 125 may be made from an aluminum alloy, stainless steel alloy, or other thermally conductive material, and is designed to structurally support the other components in the multizone target assembly 124.

In another aspect, the temperature the target sections 127 and bonded region(s) 126B are cooled by use of a plurality of cooling channels 126A formed in the insulator 126, or target sections 127. In one aspect, a heat exchanging fluid is delivered through the cooling channels 126A to transfer the heat generated during processing away from the target sections 127. In one aspect, the heat exchanging fluid is delivered from a conventional heat exchanging fluid source (not shown) that is adapted to deliver the heat exchanging fluid at a desired temperature. In one aspect, the conventional heat exchanging fluid source is adapted to control the temperature of the heat exchanging fluid delivered to the cooling channels 126A by use of a conventional refrigeration unit, resistive heater, and/or theromoelectric device. The heat exchanging fluid may be, for example, a gas (e.g., helium, nitrogen, or argon) or a liquid (e.g., DI water). In one aspect, the heat exchanging fluid is a gas, such as helium (He), that is delivered to the cooling channels 126A and maintained at a pressure between 500 milliTorr to about 50 Torr to transfer heat from the target sections 127 to the insulator 126 and backing plate 125. In another aspect, a flow of helium is delivered to the cooling channels 126A to transfer heat from the target sections 127 to the insulator 126 and backing plate 125. The cooling channels 126A may be useful to prevent the material in the bonded regions 126B, for example, indium braze materials or polymeric materials from overheating, which can cause the adhesive properties of the bonded region 126B to fail. The cooling channels 126A may be about 0.001 inches to about 1 inch in height (e.g., distance from the target section 127), while the width of the cooling channels 126A may be optimized to assure adequate bonding area of the bonded regions 126B formed between the insulator 126 and the target sections 127 versus adequate cooling capacity.

Referring to FIGS. 2 and 6, in one embodiment of the process chamber 10, a vacuum pump 28 is used to evacuate the target backside region 21 to reduce the stress induced in the multizone target assembly 124 due to the pressure differential created between the processing region 15 and the target backside region 21. The reduction in the pressure differential across the multizone target assembly 124 can be important for process chambers 10 that are adapted to process large area substrates greater than 2000 cm² to prevent the large deflections of the center of the multizone target assembly 124. Large deflections are often experienced even when the pressure differential is about equal to atmospheric pressure (e.g., 14 psi).

Referring to FIGS. 2 and 7A, in one aspect of the multizone target assembly 124, a gap “G” is formed between the target sections 127 to electrically isolate the target sections 127. The gap “G” may be between about 0.05 and about 100 millimeters (mm). In one aspect, the gap “G” is sized to be smaller than the dark space thickness so that a plasma will not be formed in the gap “G.” Selecting a desirable gap “G” dimension will help to prevent plasma attack of the bonded regions 126B (FIG. 6). Selection of a gap “G” smaller than the dark space thickness will also help to remove a source of particles due to re-deposition of the sputtered material on the target surface and also prevent the plasma generated deposition from creating arcing path between target sections 127. One will note that the dark space thickness is dependent on the gas pressure in the processing region 15, where generally the higher the pressure the smaller the dark space thickness.

FIG. 7A is vertical cross-sectional view of one embodiment of the multizone target assembly 124 that has a process gas delivery assembly 136 that contains at least one gas source 132, at least one gas channel 133 and at least one exit port 134 that are adapted to deliver a processing gas (element “A”) to the processing region 15. In one embodiment of the process gas delivery assembly 136, at least two or more of the exit ports 134 are connected to a separate gas channels 133 and gas sources 132 to deliver a different concentrations or flow rates of a desired processing gas to the processing region 15. The processing gasses may include inert gases, such as argon (Ar) or helium (He), and/or reactive gases that may be used for reactive sputtering processes, such as nitrogen (N₂), hydrogen (H₂) or oxygen (O₂). Since the density of the generated plasma during processing is related to the localized pressure in the processing region 15, controlling the gas flow and gas flow distribution into the processing region 15 can be optimized and controlled. In one aspect, a plurality of exit ports 134 spaced across the multizone target assembly 124 are used to deliver a desired gas distribution to the processing region 15. In one aspect, a flow restrictor 138 is added in at least one of the gas channels 133 to control and balance the flow of the process gas through the plurality of exit ports 134.

In one aspect of the process gas delivery assembly 136, as shown in FIG. 7A, at least one gas channel 133 and at least one exit port 134 are adapted to deliver a processing gas to the processing region 15 through a space 135 formed between the target sections (e.g., elements 127A and 127B). In one aspect, a plurality of exit ports 134 are uniformly spaced along the length of the gap “G” formed between at least two of the target sections to deliver a uniform gas flow into the processing region 15. FIG. 7B illustrates a plan view of one embodiment of the multizone target assembly 124 that contains three target sections 127A, 127B and 127C that have a plurality of exit ports 134 formed in the gaps “G” between the target sections (i.e., between 127A and 127B, and between 127B and 127C).

In another aspect of the process gas delivery assembly 136, one or more of the exit ports 134 are formed through the middle of at least one of the target sections 127 (e.g., element 137 formed in 127A). FIG. 7C illustrates a plan view of one embodiment of the multizone target assembly 124 that contains two target sections 127A and 127B, and one target section (element 127A) has an exit port 134 that is adapted to deliver a process gas through the center (element “C”) of the target section by use of a gas source (not shown). FIG. 7D illustrates a plan view of one embodiment of the multizone target assembly 124 that has plurality of exit ports that are adapted to deliver a process gas to the processing region 15 through the target sections 127A (element 134A) and through the target sections 127B (element 134B) by use of one or more gas sources (not shown) connected to the exit ports (elements 134A and 134B).

In one aspect, as shown in FIG. 7A, the process gas delivery assembly 136 has at least two exit ports, where at least one exit port 134 is adapted to deliver gas through a region formed (element 137) in the middle of a target section 127 and at least one exit port 134 is adapted to deliver the process gas through the gap “G” formed between at least two of the target sections. The various embodiments of the illustrates in FIGS. 7A-D may be especially effective for use in reactive sputtering process (e.g., TaN, TiN) since the process uniformity is related to uniformity of the reactive gas delivered to the processing region 15. In this configuration it may be desirable to deliver reactive gases from a gas source 132 to the processing region 15 through a plurality of exit ports 134 that are evenly distributed across the multizone target assembly 124.

In one aspect, it is desirable to shape the edges of the target sections 127 so that they overlap, as shown in FIGS. 6 and 7A, to in a sense hide the insulator 126 and bonded region 126B from the plasma formed in the processing region 15. Referring to FIG. 7A, in one embodiment it may be useful to bevel the edges of the target sections 127 near the region between them to form an overlapping feature which “hides” the bonded region 126B. In one aspect, it may be desirable to remove all sharp edges of the target sections 127 to reduce the current density emitted from these areas and thus make the electron emission and plasma generation more uniform in the processing region 15.

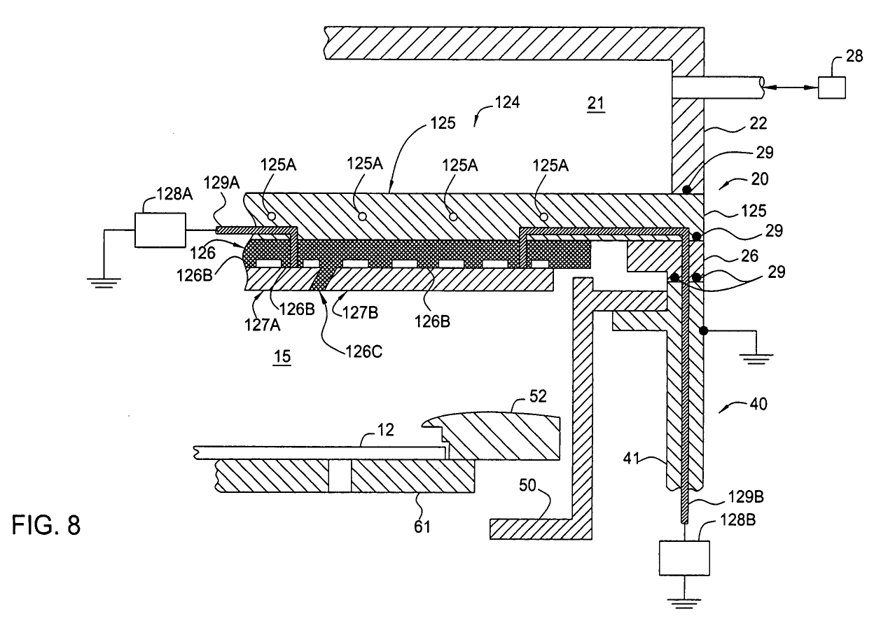

FIG. 8 illustrates one embodiment in which the target sections 127 are positioned in one or more recesses in the insulator 126. In this configuration the insulator protrusions 126C formed in the insulator 126 are used to fill the gap(s) between the target regions 127. The use of the insulator protrusions 126C can help to prevent the generation of a plasma between the target regions and electrically isolate the target regions 127. In one aspect, it may be desirable to add features (e.g., high aspect ratio trenches, recesses, overhangs) to the insulator protrusions 126C to prevent any re-deposited target material from forming an arcing path between the target regions 127.

While the foregoing is directed to embodiments of the present invention, other and further embodiments of the invention may be devised without departing from the basic scope thereof, and the scope thereof is determined by the claims that follow.

We claim:

1. A method of depositing a thin film on a large area substrate, comprising:
electrically biasing a first target section of a multizone target assembly at a first bias using a first power supply;
electrically biasing a second target section of the multizone target assembly at a second bias using a second power supply; and
controlling the deposition profile received on a substrate surface by controlling the bias delivered by the first power supply and the second power supply.

2. The method of claim 1, wherein the large area substrate has a processing surface that has surface area that is at least 19,500 cm².

3. The method of claim 1, wherein controlling the deposition profile comprises:
adjusting the magnitude of the first bias as a function of time, wherein the magnitude of first bias at a first time is equal to X; and
adjusting the magnitude of the second bias as a function of time, wherein the magnitude of second bias at a first time is equal to Z, wherein the magnitude of X is greater than Z.

4. The method of claim 1, wherein controlling the deposition profile comprises:
modulating the power delivered to a first target section at a first pulse frequency and at a first bias power level using the first power supply;
modulating the power delivered to a second target section at a second pulse frequency and at a second bias power level using the second power supply; and
synchronizing the modulation of the power to the first target section and the second target section to improve the uniformity of the deposition process completed on the substrate.

5. The method of claim 1, further comprising: cooling the first target section and the second target section by bringing a heat exchanging fluid in thermal contact with the first target and second target sections.

6. The method of claim 1, further comprising:
providing a process gas to the processing region through a port formed in the first target section, the second target section, or a gap formed between the first target section and the second target section.

7. The method of claim 1, further comprising: biasing an RF biasable element positioned within a substrate support using a RF power source.

8. A method of depositing a thin film on a substrate, comprising:
electrically biasing a first target section of a multizone target assembly at a first bias using a first power supply;
electrically biasing a second target section of a multizone target assembly at a second bias using a second power supply;
positioning a first magnetron assembly over the first target section using a first actuator, wherein a magnet in the first magnetron is magnetically coupled to a processing region that is adjacent to a surface of the first target section;
positioning a second magnetron assembly over the second target section using a second actuator, wherein a magnet in the second magnetron is magnetically coupled to the processing region that is adjacent to a surface of the second target section; and
controlling the deposition profile received on a substrate surface by controlling the first bias delivered by the first power supply, the second bias delivered by the second power supply, the position of the first magnetron assembly and the position of the second magnetron assembly.

9. The method of claim 8, wherein the magnet in the first magnetron or the magnet in the second magnetron is an electromagnet.

10. The method of claim 8, wherein controlling the deposition profile comprises:
adjusting the magnetic field strength delivered to a processing region that is adjacent to the first target section using a first electromagnet.

11. The method of claim 8, wherein the magnitude of the first bias is greater than the magnitude of the second bias.

12. The method of claim 8, further comprising:
providing a process gas to the processing region through a port formed in the first target section, the second target section, or a gap formed between the first target section and the second target section.

13. A method of depositing a thin film on a substrate, comprising:
providing a process gas to a processing region through a port formed in a multizone target assembly, wherein the processing region is formed between the multizone target assembly and a substrate positioned on a substrate support; and
depositing a layer onto a surface of the substrate positioned on the substrate support by biasing a first target region of the multizone target assembly at a first bias and a second target region of the multizone target assembly at a second bias, wherein the first bias voltage is more cathodic than the second bias voltage.

14. A method of depositing a thin film on a substrate, comprising:
electrically biasing a first target section of a multizone target assembly at a first bias using a first power supply;
electrically biasing a second target section of a multizone target assembly at a second bias using a second power supply; and
positioning a magnetron assembly over the first target section and the second target section using an actuator, wherein a first magnet in the magnetron assembly is magnetically coupled to a processing region that is adjacent to a surface of the first target section and a second magnet in the magnetron assembly is magnetically coupled to a processing region that is adjacent to a surface of the second target section;
controlling the deposition profile received on a substrate surface by controlling the first bias delivered by the first power supply, the second bias delivered by the second power supply, and the position of the magnetron assembly.

15. The method of claim 14, where in controlling the deposition profile comprises:
adjusting the magnetic field strength delivered from the first magnet to the processing region that is adjacent to the first target section, wherein the first magnet is an electromagnet.

16. The method of claim 14, further comprising:
providing a process gas to the processing region through a port formed in the first target section, the second target section, or a gap formed between the first target section and the second target section.
